(19) United States
(12) Patent Application Publication
(10) Pub. No.: US 2013/0207736 A1
(43) Pub. Date: Aug. 15, 2013

(54) RESISTANCE MEASURING CIRCUIT, RESISTANCE MEASURING METHOD, AND IMPEDANCE CONTROL CIRCUIT

(71) Applicant: SK hynix Inc., (US)

(72) Inventors: Dong-Uk LEE, Icheon (KR); Keun-Soo SONG, Icheon (KR)

(73) Assignee: SK HYNIX INC., Icheon (KR)

(21) Appl. No.: 13/716,051

(22) Filed: Dec. 14, 2012

(30) Foreign Application Priority Data
Feb. 14, 2012 (KR) 10-2012-0014635

(51) Int. Cl. G01R 27/02; H03H 5/00

(52) U.S. Cl. CPC G01R 27/02; H03H 5/00
USPC 333/17.3; 324/705

(57) ABSTRACT

A resistance measuring method includes: measuring a resistance value of a first path which is formed from an interface pad through a resistor unit to a ground node; measuring a resistance value of a second path which is formed from the interface pad to the ground node but does not pass through the resistor unit; and calculating a resistance value of the resistor unit by subtracting the resistance value of the second path from the resistance value of the first path.

### CROSS-REFERENCE TO RELATED APPLICATIONS

The present application claims priority of Korean Patent Application No. 10-2012-0014635, filed on Feb. 14, 2012, which is incorporated herein by reference in its entirety.

### BACKGROUND

1. Field

Exemplary embodiments of the present invention relate to a resistance measuring circuit, a resistance measuring method, and an impedance control circuit for generating an impedance code for controlling impedance using an internal resistance value measured by the resistance measuring circuit or method.

2. Description of the Related Art

An integrated circuit chip includes electric elements such as resistors and capacitors, and the stability and reliability of the integrated circuit chip depends on electric characteristics of the electric elements. For example, when an actual resistance value of a resistor embedded in the integrated circuit chip deviates from a range of resistance values designed for a normal operation, the integrated circuit chip may perform an abnormal operation. Therefore, it is important to precisely measure the characteristics of the electric elements embedded in the integrated circuit chip so as to prevent such an abnormal operation in advance.

In general, a resistance measuring device is connected to a resistance measurement pad of an integrated circuit chip in order to measure a resistance value of a resistor embedded in the integrated circuit chip. However, it is difficult to precisely measure the resistance value of the resistor embedded in the integrated circuit chip due to additional resistance values resulted from the resistance measuring device and the resistance measurement pad coupling the resistance measuring device to the integrated circuit chip. Thus, there is a need to develop a method of precisely measuring the resistance value of the resistor embedded in the integrated circuit chip.

Meanwhile, a swing width of a signal interfaced between semiconductor devices has gradually decreased with an increasing operation speed of electronic devices. This aims at minimizing a delay time required for signal transmission. However, such a decrease of the signal swing width may lead to detrimental effects caused by external noises and signal reflection caused by impedance mismatching at the interface. More specifically, the impedance mismatching occurs due to external noises, variations in power supply voltage levels, changes in operation temperature, changes in manufacturing processes, or the like. Such an impedance mismatching not only renders transmission of data at a high speed difficult, but also distorts data outputted from a data output terminal of a semiconductor device. Then, when a semiconductor device on a receiver side receives a distorted signal through an input terminal thereof, problems such as setup/hold failure and wrong determination of an input level may occur.

As a result, a memory device requiring a high operation speed includes an impedance matching circuit which is provided around an input pad inside an integrated circuit chip. The impedance matching circuit may be referred to as an on-die termination circuit. According to a typical on-die termination scheme, source termination is performed by an output circuit on a transmitter side, and parallel termination is performed by a termination circuit connected in parallel to a receiving circuit on a receiver side.

Among impedance matching technologies, ZQ calibration refers to a process of generating an impedance code which is changed according to PVT (process, voltage, and temperature) variations. The impedance code generated as a result of the ZQ calibration may be used to control a termination impedance value.

Hereafter, a calibration circuit to perform calibration will be described.

FIG. 1 illustrates a conventional calibration circuit.

Referring to FIG. 1, the conventional calibration circuit includes a pull-up impedance unit 12, a dummy impedance unit 30, a pull-down impedance unit 23, first and second comparison units 10 and 21, and first and second counter units 11 and 22.

When a calibration operation starts, the first comparison unit 10 compares a voltage of a first node ND1 with a reference voltage VREF, and generates a first up/down signal UP/DN1 according to the comparison result. An external resistor R_ZQ is coupled to the pull-up impedance unit 12 through a calibration pad ZQ_PAD and the first node ND1. The voltage of the first node ND1 is determined by a ratio between resistance values of the pull-up impedance unit 12 and the external resistor R_ZQ. Hereafter, suppose the external resistor R_ZQ is 240Ω, and the reference voltage VREF is set to VDD/2.

The first counter unit 11 receives the first up/down signal UP/DN1 and generates a pull-up impedance code PCODE<1:M>. The pull-up impedance code PCODE<1:M> turns on/off parallel resistors inside the pull-up impedance unit 12 to control the impedance value of the pull-up impedance unit 12. The impedance value of each parallel resistor of the pull-up impedance unit 12 may be designed to have a binary weight. The controlled impedance value of the pull-up impedance unit 12 changes a level of the voltage of the first node ND1, and the above-described operation is repeated until the total impedance value of the pull-up impedance unit 12 becomes substantially equal to the impedance value of the external resistor R_ZQ (pull-up calibration).

The pull-up impedance code PCODE<1:M> generated by the above-described pull-up calibration operation is inputted to the dummy impedance unit 30 so that the total impedance value of the dummy impedance unit 30 becomes substantially equal to the total impedance value of the pull-up impedance unit 12.

Then, a pull-down calibration operation starts. The pull-down calibration operation is performed in a similar manner to the pull-up calibration operation as described above. The second comparison unit 21 and the second counter unit 22 are used to perform calibration such that a voltage of a second node ND2 becomes substantially equal to the reference voltage VREF. Consequently, the total impedance value of the pull-down impedance unit 23 becomes substantially equal to the total impedance value of the dummy impedance unit 30 (pull-down calibration).

However, the conventional calibration method described above requires the external resistor ZQ, which may increase a system cost. In addition, when only one calibration pad ZQ PAD exists, it is difficult to perform the calibration operation in a multi-chip package.

### SUMMARY

An embodiment of the present invention is directed to a resistance measuring circuit and method capable of precisely measuring a resistance value of a resistor inside an integrated circuit chip.

In accordance with an embodiment of the present invention, a resistance measuring method includes: measuring a resistance value of a first path from an interface pad through a resistor unit to a ground node; measuring a resistance value of a second path from the interface pad to the ground node without passing through the resistor unit; and calculating a resistance value of the resistor unit by subtracting the resistance value of the second path from the resistance value of the first path.

In accordance with an embodiment of the present invention, a resistance measuring circuit includes: an interface pad; a resistor unit; a path control unit configured to form a first path from the interface pad through the resistor unit to a ground node or a second path from the interface pad to the ground node without passing through the resistor unit in response to a path control signal which transitions from one logic level to another logic level; and a resistance measuring unit connected to the interface pad and configured to measure a resistance value of the first path or a resistance value of the second path in response to the path control signal.

Another embodiment of the present invention is directed to an impedance control circuit to generate an impedance code for impedance matching using an internal resistor whose resistance value is precisely measured through the resistance measuring circuit or method.

In accordance with an embodiment of the present invention, an impedance control circuit includes: an internal resistor unit whose resistance value is controlled in response to a control code from outside; a code generation unit configured to generate an impedance code for controlling a termination impedance value, using a voltage of an impedance node connected to the internal resistor unit; and an impedance unit configured to have an impedance value decided by the impedance code, and connected to the impedance node.

### BRIEF DESCRIPTION OF THE DRAWINGS

FIG. 1 illustrates a conventional calibration circuit.

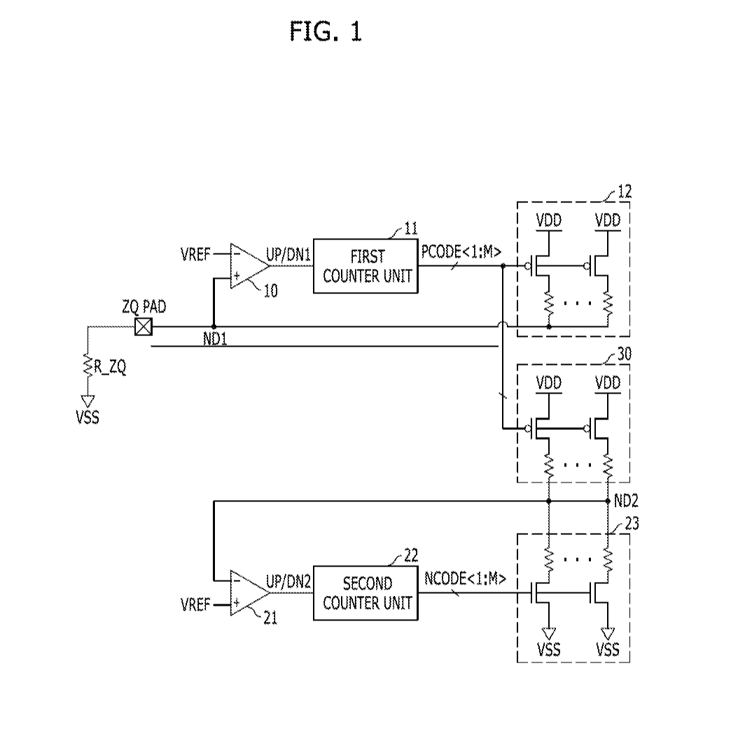

FIG. 2 illustrates a resistance measuring circuit in accordance with an embodiment of the present invention.

FIG. 3 is a flow chart showing an operation of the resistance measuring circuit illustrated in FIG. 2.

FIG. 4 illustrates a resistance measuring circuit in accordance with another embodiment of the present invention.

FIG. 5 is a flow chart showing an operation of the resistance measuring circuit illustrated in FIG. 4.

FIG. 6 illustrates an impedance control circuit in accordance with an embodiment of the present invention.

FIG. 7 is a flow chart showing the overall operation of the impedance control circuit illustrated in FIG. 6.

FIG. 8 illustrates a semiconductor device in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

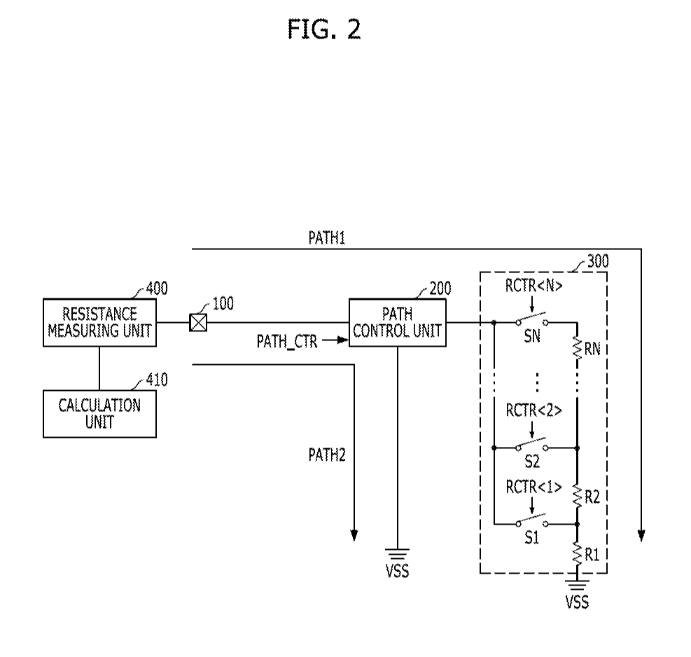

FIG. 2 is a diagram illustrating a resistance measuring circuit in accordance with an embodiment of the present invention.

The resistance measuring circuit is configured to measure a resistance value of an internal resistor in an integrated circuit chip. Referring to FIG. 2, the resistance measuring circuit includes an interface pad 100, a path control unit 200, a resistor unit 300, a resistance measuring unit 400, and a calculation unit 410.

The path control unit 200 is configured to form an electrical path through which the interface pad 100 is coupled to a ground node. In accordance with an embodiment, when a path control signal PATH_CTR is enabled to, e.g., a high level, the path control unit 200 operates to form a first path PATH1 from the interface pad 100 to the ground node via the resistor unit 300. In contrast, when the path control signal PATH_CTR is disabled to, e.g., a low level, the path control unit 200 operates to form a second path PATH2 from the interface pad 100 to the ground node without passing through the resistor unit 300. Here, the path control signal PATH_CTR is a signal provided from an external node outside the integrated circuit chip. Whenever a control code RCTR<1:N> is inputted from the external node, the path control signal PATH_CTR having a high logic level or a low logic level may be inputted to measure a resistance value of the resistor unit 300 corresponding to the control code RCTR<1:N> as described below.

The resistor unit 300 may be configured to have a constant or variable resistance value. FIG. 2 illustrates a case in which the resistor unit 300 is configured to have a variable resistance value according to the control code RCTR<1:N>. In an embodiment, the resistor unit 300 may include a plurality of resistors R1 to RN connected in series and a plurality of switches S1 to SN. Each of the switches S1 to SN is turned on/off in response to a corresponding bit of the control code RCTR<1:N>. Specifically, when a K-th bit RCTR<K> of the control code RCTR<1:N> corresponding to a K-th switch SK is at a high logic level and the other bits of the control code RCTR<1:N> are at a low logic level, only the K-th switch SK is turned on, and the other switches are turned off, K being in a range of 1 to N. In this case, the resistance value of the resistor unit 300 is the sum of resistance values of the first to K-th resistors R1 to RK, i.e., R1+R2+ . . . +RK. For example, when only the first bit RCTR<1> of the control code RCTR<1:N> corresponding to the first switch S1 is at a high logic level and the other bits RCTR<2:N> are at a low logic level, only the first switch S1 is turned on, and the other switches S2 to SN are turned off. In this case, the resistance value of the resistor unit 300 corresponds to a resistance value of the first resistor R1. As another example, when only the second bit RCTR<2> of the control code RCTR<1:N> corresponding to the second switch S2 is at a high logic level and the other bits RCTR<1> and RCTR<3:N> are at a low logic level, only the second switch S2 is turned on, and the other switches S1 and S3 to SN are turned off. In this case, the resistance value of the resistor unit 300 corresponds to the sum of resistance values of the first and second resistors R1 and R2, i.e., R1+R2.

The resistance measuring unit 400 is configured to measure a resistance value of a path formed by the path control unit 200. In an embodiment, the resistance measuring unit 400 is connected to the interface pad 100 to measure a resistance value of the first path PATH1 when the path control signal PATH_CTR is activated to, e.g., a high logic value, and to measure a resistance value of the second path PATH2 when the path control signal PATH_CTR is deactivated to, e.g., a low logic value. Here, the resistance value of the first path PATH1 is substantially the same as the sum of resistance values of the resistance measuring unit 400, the interface pad 100, the path control unit 200, and the resistor unit 300. Hereafter, resistance values of the resistance measuring unit 400, the interface pad 100, and the path control unit 200 are represented by R_MSR, R_PAD, and R_PATH, respectively, and the resistance value of the resistor unit 300 is represented by R_R, for the simplicity of description. Therefore, the resistance value of the first path PATH1 is expressed as (R_MSR+R_PAD+R_PATH+R_R). On the other hand, the resistance value of the second path PATH2 is equal to the sum of the resistance values of the resistance measuring unit 400, the interface pad 100, and the path control unit 200. That is, the resistance value of the second path PATH2 is expressed as (R_MSR+R_PAD+R_PATH).

The calculation unit 410 is configured to precisely calculate the resistance value of the resistor unit 300. In an embodiment, the calculation unit 410 receives the resistance values of the first and second paths PATH1 and PATH2 and subtract the resistance value of the second path PATH2, i.e., (R_MSR+R_PAD+R_PATH), from the resistance value of the first path PATH1 i.e., (R_MSR+R_PAD+R_PATH+R_R). In this manner, the calculation unit 410 may calculate the resistance value R_R of the resistor unit 300.

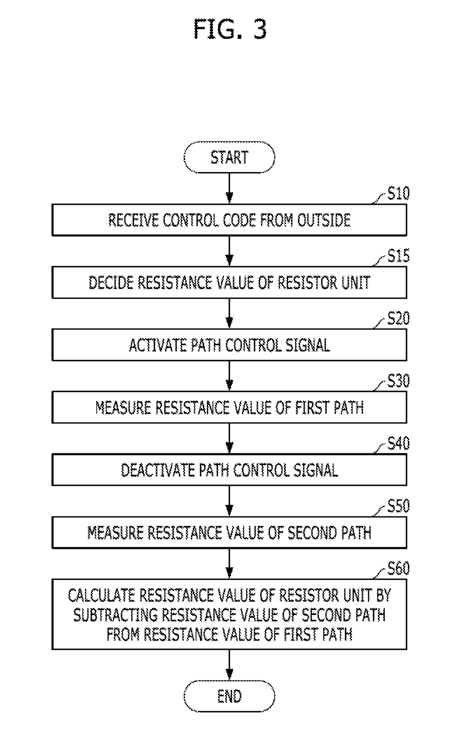

FIG. 3 is a flow chart showing an operation of the resistance measuring circuit illustrated in FIG. 2 according to an embodiment of the present invention.

First, the control code CTRL<1:N> is inputted to the resistance measuring circuit from outside at step S10. Hereafter, a case in which the first bit RCTR<1> of the control code RCTR<1:N> is at a high logic level and the other bits RCTR<2:N> are at a low logic level will be described as an example.

The resistance value of the resistor unit 300 is decided in response to the control code RCTR<1:N> at step S15. Since the first bit RCTR<1> of the control code RCTR<1:N> is at a high logic level, only the first switch 51 corresponding to the first bit RCTR<1> is turned on, and the other switches S2 to SN are turned off. As a result, the resistance value of the first resistor R1 is determined as the resistance value R_R of the resistor unit 300.

Then, the path control signal PATH_CTR is activated at step S20. The path control unit 200 couples the interface pad 100 and the resistor unit 300 in response to the activated path control signal PATH_CTR, thereby forming the first path PATH1 from the interface pad 100 to the ground node via the resistor unit 300.

The resistance measuring unit 400 measures the resistance value of the first path PATH1 at step S30. Here, the resistance value of the first path PATH1 is equal to (R_MSR+R_PAD+R_PATH+R_R). In addition, the measured resistance value of the first path PATH1 is transmitted to the calculation unit 410.

Subsequently, the path control signal PATH_CTR is deactivated at step S40. In this case, the path control unit 200 couples the interface pad 100 and the ground node in response to the deactivated path control signal PATH_CTR. Accordingly, the path control unit 200 forms the second path PATH2 from the interface pad 100 to the ground node without passing through the resistor unit 300.

At step S50, the resistance measuring unit 400 measures the resistance value of the second path PATH2. Here, the resistance value of the second path PATH2 corresponds to (R_MSR+R_PAD+R_PATH). Then, the measured resistance value of the second path PATH2 is transmitted to the calculation unit 410.

At step S60, the calculation unit 410 subtracts the resistance value of the second path PATH2, i.e., (R_MSR+R_PAD+R_PATH), from the resistance value of the first path PATH1, i.e., (R_MSR+R_PAD+R_PATH+R_R). As a result, the resistance value R_R of the resistor unit 300 is calculated by the calculation unit 410.

According to the embodiment of the present invention described above, the resistance value of the resistor unit 300 may be measured by eliminating the measured resistance value R_MSR, R_PAD, and R_PATH of the second path PATH2 from the measured resistance value of the first path PATH1.

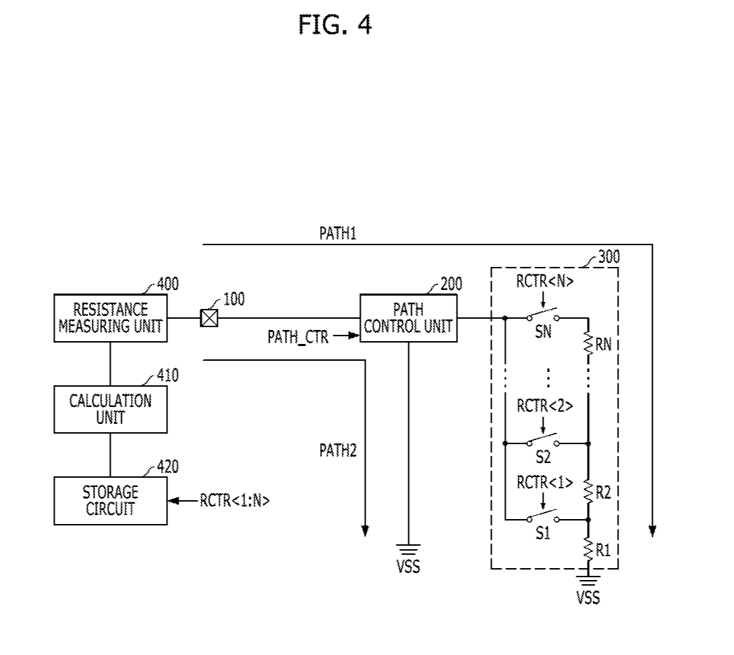

FIG. 4 is a diagram illustrating a resistance measuring circuit according to another embodiment of the present invention.

Unlike the resistance measuring circuit shown in FIG. 2, the resistance measuring circuit of FIG. 4 continues to measure a resistance value of the resistor unit 300 by changing bit values of a control code RCTR<1:N> until the measured resistance value of the resistor unit 300 reaches a target resistance value, then stores bit values of the control code RCTR<1:N> corresponding to the target resistance value in the storage circuit 420. Hereafter, when a difference between the resistance value of the resistor unit 300 and the target resistance value falls within a predetermined range, the resistance value of the resistor unit 300 is determined to reach the target resistance value. Hereafter, the differences between the resistance measuring circuit shown in FIG. 4 and the resistance measuring circuit shown in FIG. 2 will be described in detail.

Referring to FIG. 4, the resistance measuring circuit includes a resistor unit 300, a path control unit 200, an interface pad 100, a resistance measuring unit 400, a calculation unit 410, and a storage circuit 420. That is, the resistance measuring circuit illustrated in FIG. 4 further includes the storage circuit 420 compared to the resistance measuring circuit illustrated in FIG. 2.

The interface pad 100, the resistance measuring unit 400, and the calculation unit 410 are similar to those illustrated in FIG. 2.

The resistor unit 300 has a variable resistance value. Specifically, the resistor unit 300 is designed in such a manner that the resistance value thereof is decided in response to the control code RCTR<1:N>. In this case, the resistor unit 300 illustrated in FIG. 4 may have the similar configuration to the resistor unit illustrated in FIG. 2.

In addition, the path control unit 200 illustrated in FIG. 4 may have the similar configuration to the path control unit 200 illustrated in FIG. 2. Thus, to avoid duplicate explanation, detailed descriptions to the interface pad 100, the resistor unit 300, the resistance measuring unit 400, and the calculation unit 410, and the path control unit 200 will be omitted in this embodiment.

The storage circuit 420 is configured to store the control code RCTR<1:N> when the resistance value of the resistor unit 300 calculated by the calculation unit 410 is equal to the target resistance value. In an embodiment, the storage circuit 420 may include a comparison unit and a storage unit which are not illustrated in FIG. 4. The comparison unit of the storage circuit 420 is configured to compare the resistance value of the resistor unit 300, which is calculated by the calculation unit 410, to the target resistance value, and outputs an output signal to the storage unit of the storage circuit 420. The storage unit is configured to store the control code RCTR<1:N> in response to the output signal of the comparison unit when the resistance value of the resistor unit 300 is equal to the target resistance value. For instance, the storage unit may be implemented with a fuse circuit which includes one or more fuses and outputs a signal of which a logic value depends on whether the fuses are cut or not. In this case, the control code RCTR<1:N> is programmed into the fuse circuit. A method of programming the fuse circuit may include an electrical cutting method or laser cutting method. More specifically, the electrical cutting method is to cut a target fuse by applying an over-current to the target fuse, and the laser cutting method is to cut a target fuse using laser beams.

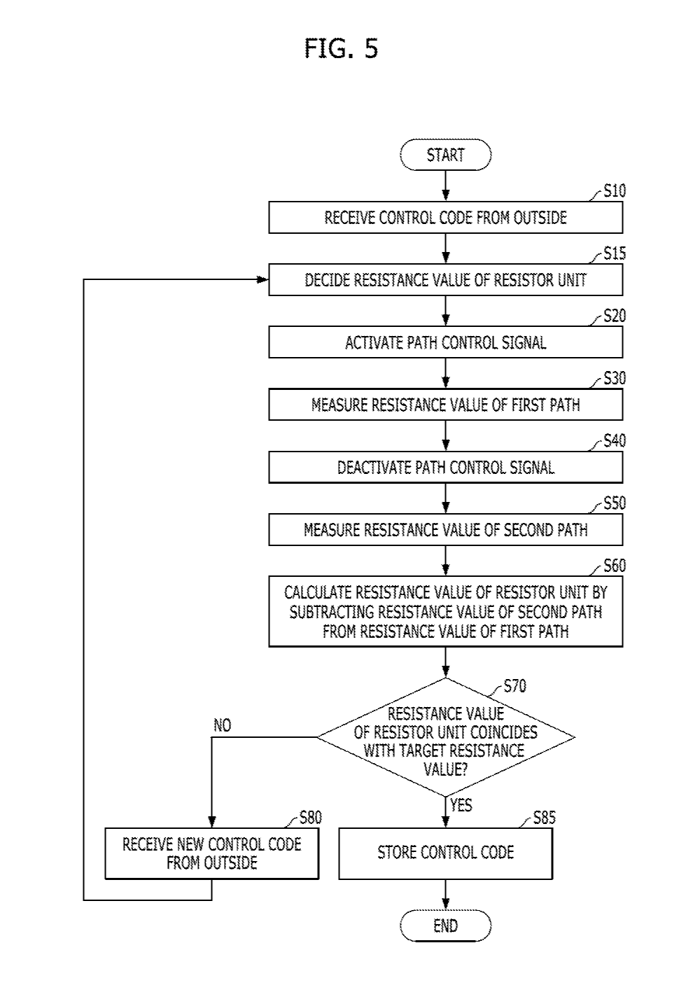

FIG. 5 is a flow chart showing an operation of the resistance measuring circuit illustrated in FIG. 4 according to an embodiment of the present invention.

In FIG. 5, steps S10 to S60 are performed in the same manner as the steps S10 to S60 described in FIG. 3. Thus, the detailed descriptions thereof are omitted herein.

As described above, the storage circuit 420 compares the resistance value of the resistor unit 300, which is calculated by the calculation unit 410, to the target resistance value at step S70. When the resistance value of the resistor unit 300 is not equal to the target resistance value, the resistance measuring circuit receives another control code RCTR<1:N> from outside at step S80. For instance, when the control code RCTR<1:N> is inputted from outside in a first time, only the first bit RCTR<1> of the control code RCTR<1:N> is at a high logic level, and the other bits RCTR<2:N> are at a low high level. In this case, the first switch S1 corresponding to the first bit RCTR<1> among the switches S1 to SN is turned on while the other switches S2 to SN are turned off. Therefore, the resistance value of the resistor unit 300 is decided as the resistance value of the first resistor R1. Furthermore, when the control code RCTR<1:N> is inputted from outside in a second time, only the second bit RCTR<2> of the control code RCTR<1:N> is at a high logic level, and the other bits RCTR<1> and RCTR<3:N> are at a low logic level. In this case, the second switch S2 corresponding to the second bit RCTR<2> among the switches S1 to SN is turned on while the other switches S1 and S3 to SN are turned off. As a result, the resistance value of the resistor unit 300 is decided as the sum of the resistance values of the first and second resistors R1 and R2, i.e., (R1+R2). In general, when the control code RCTR<1:N> is inputted from outside in a K-th time, the K-th bit RCTR<K> of the control code RCTR<1:N> is at a high logic level while the other bits RCTR<1:K−1> and RCTR<K+1:N> are at a low high level. In this case, the K-th switch SK corresponding to the K-th bit RCTR<K> among the switches S1 to SN is turned on while the other switches S1 to SK−1 and SK+1 to SN are turned off. Therefore, the resistance value of the resistor unit 300 is decided as the sum of the resistance values of the first to K-th resistors R1 to RK, i.e., (R1+R2+ . . . +RK). In this manner, the resistance value of the resistor unit 300 may continuously increase until the resistance value of the resistor unit 300 reaches the target resistance value. Meanwhile, the resistance measuring circuit repeats the steps S15 to S70 whenever the resistance measuring circuit receives a new control code RCTR<1:N>. According to another embodiment, step S50 may be performed only once because the resistance value of the second path PATH2, i.e., (R_MSR+R_PAD+R_PATH), does not change depending on the control code RCTR<1:N>.

When the resistance value of the resistor unit 300, which is calculated by the calculation unit 410, reaches the target resistance value, the storage circuit 420 stores the control code RCTR<1:N> at that time at step S85. In an embodiment the storage circuit 420 is configured to include a fuse circuit, and the control code RCTR<1:N> is programmed into the fuse circuit.

In accordance with the embodiment of the present invention, the resistance value of the resistor unit 300 is measured by eliminating the resistance values R_MSR, R_PAD, and R_PATH from the measured resistance value of the first path PATH1. In addition, the control code RCTR<1:N> corresponding to the target resistance value is stored in the storage circuit 420 when the measured resistance value of the resistor unit 300 is equal to the target resistance value. In this manner, an integrated circuit chip designed to perform a specific operation using the resistor unit 300 may set the resistance value of the resistor unit 300 to the target resistance value using the control code RCTR<1:N> before it performs the specific operation. As a result, the stability and reliability of the integrated circuit chip may be improved.

Hereafter, an impedance control circuit for generating an impedance code to control an impedance value using an internal resistor unit will be described.

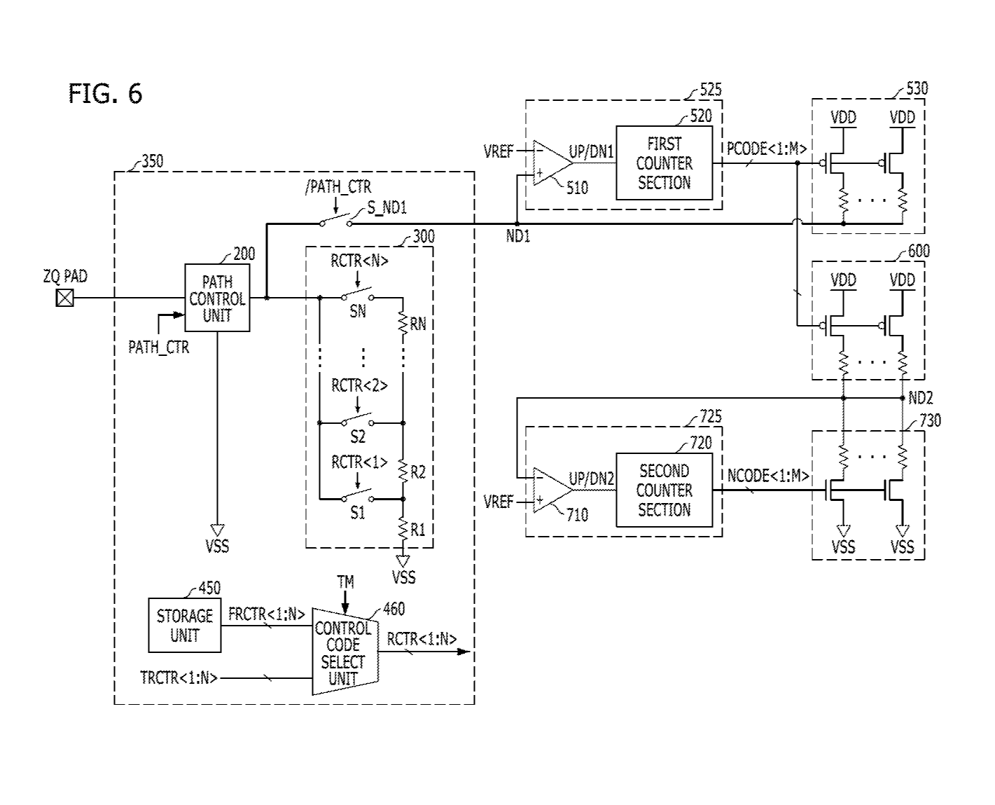

FIG. 6 is a diagram illustrating an impedance control circuit according to an embodiment of the present invention.

Referring to FIG. 6, the impedance control circuit includes a resistor circuit 350, first and second code generation units 525 and 725, a pull-up impedance unit 530, a dummy impedance unit 600, and a pull-down impedance unit 730.

The resistor circuit 350 may include a path control unit 200, an internal resistor unit 300, a storage unit 450, and a control code select unit 460.

The path control unit 200 is configured to form an electrical path through which a calibration pad ZQ PAD is coupled to a ground node. In an embodiment, when a path control signal PATH_CTR is activated, the path control unit 200 forms a first path PATH1 from the calibration pad ZQ PAD to the ground node via the internal resistor unit 300. In contrast, when the path control signal PATH_CTR is deactivated, the path control unit 200 forms a second path PATH2 from the calibration pad ZQ PAD to the ground node without passing through the internal resistor unit 300. Here, the path control signal PATH_CTR is a signal provided from outside. In a resistance measurement mode, e.g., when a test mode signal TM is at a high logic level, the path control signal PATH_CTR is at a high logic level or a low logic level to form one of two different electrical paths PATH 1 and PATH2 so as to measure the resistance value of the internal resistor unit 300 when a control code TRCTR<1:N> is inputted from outside. In contrast, in a normal mode, e.g., when the test mode signal TM is at a low logic level, the path control signal PATH_CTR is at a low logic level to activate a first node switch S_ND1 as described below. The internal resistor unit 300 is coupled to a first node ND1, and has a variable resistance value in response to a control code RCTR<1:N>. Specifically, the resistance value of the internal resistor unit 300 may be determined in response to the control code RCTR<1:N> as described above with reference to FIGS. 2 and 4. To avoid duplicate explanation, detailed descriptions to the resistor unit 300 will be omitted in this embodiment.

Referring to FIG. 6, the resistor circuit 350 further includes the first node switch S_ND1 which is positioned between the first node ND1 and the internal resistor unit 300 and turned on in response to an inverted path control signal /PATH_CTR. The first node switch S_ND1 may be turned on when the inverted path control signal /PATH_CTR is at a high logic level, and turned off when the inverted path control signal /PATH_CTR is at a low logic level.

The storage unit 450 is configured to store the control code RCTR<1:N> as a control code FRCTR<1:N> when the resistance value of the internal resistor unit 300 is equal to a target resistance value. In an embodiment, the storage unit 450 may be implemented with a fuse circuit which includes one or more fuses and is configured to output a signal whose logic value depends on whether the fuses are cut or not. In the resistance measurement mode, e.g., when the test mode signal TM is at a high logic level, the storage unit 450 stores as the control code FRCTR<1:N> the control code RCTR<1:N> when the resistance value of the internal resistor unit 300 is equal to a target resistance value. Herein, when a difference between the resistance value of the internal resistor unit 300 and the target resistance value falls within a predetermined range, the resistance value of the internal resistor unit 300 may be considered equal to the target resistance value.

The control code select unit 460 is configured to select either the control code FRCTR<1:N> outputted from the storage unit 450 or the control code TRCTR<1:N> inputted from outside in response to the test mode signal TM, and to output the selected control code to the internal resistor unit 300. Specifically, in the resistance measurement mode, e.g., when the test mode signal TM is at a high logic level, the control code select unit 460 may select the control code TRCTR<1:N> inputted from outside and transmit the selected code TRCTR<1:N> to the internal resistor unit 300 so as to repeatedly operate the internal resistor unit 300 until the resistance value of the internal resistor unit 300 reaches the target resistance value. In contrast, in the normal mode, e.g., when the test mode signal TM is at a low logic level, the control code select unit 460 may select the control code FRCTR<1:N> outputted from the storage unit 450 and transmit the selected control code FRCTR<1:N> to the internal resistor unit 300.

The pull-up code generation unit 525 is configured to generate a pull-up impedance code PCODE<1:M> using the voltage of the first node ND1 connected to the internal resistor unit 300. In an embodiment, the pull-up code generation unit 525 may include a first comparison section 510 and a first counter section 520. The first comparison section 510 is configured to compare a reference voltage VREF to the voltage of the first node ND1 and generate a first up/down signal UP/DN1 indicating which voltage is higher than the other voltage. The first counter section 520 is configured to increase/decrease a value of the pull-up impedance code PCODE<1:M> in response to the first up/down signal UP/DN1.

The pull-up impedance unit 530 is configured to pull-up drive the first node ND1 using an impedance value thereof decided by the pull-up impedance code PCODE<1:M>. In an embodiment, the pull-up impedance unit 530 may include a plurality of PMOS transistors coupled in parallel to the first node ND1 and configured to be turned on/off in response to the respective bits of the pull-up impedance code PCODE<1:M>.

In an operation, when the impedance value of the pull-up impedance unit 530 is greater than the resistance value of the internal resistor unit 300, the voltage level of the first node ND1 becomes lower than the reference voltage VREF. Then, the first comparison section 510 outputs a down signal DN1 to decrease a binary value of the pull-up impedance code PCODE<1:M> outputted from the first counter section 520. As a result, the number of PMOS transistors which are turned on increases, thereby decreasing the impedance value of the pull-up impedance unit 530. In this manner, the voltage level of the first node ND1 increases and becomes closer to that of the reference voltage. This process may be repeated until the voltage level of the first node ND1 becomes equal to that of the reference voltage.

The dummy impedance unit 600 has the same configuration as the pull-up impedance unit 530, and is configured to pull-up a voltage level of a second node ND2 using an impedance value decided by the pull-up impedance code PCODE<1:M>.

The pull-down code generation unit 725 is configured to generate a pull-down impedance code NCODE<1:M> using the voltage of the second node ND2. In an embodiment, the pull-down code generation unit 725 may include a second comparison section 710 and a second counter section 720. The second comparison section 710 is configured to compare the reference voltage VREF to the voltage of the second node ND2 and generate a second up/down signal UP/DN2 indicating which voltage is higher than the other voltage. The second counter unit 720 is configured to increase/decrease a value of the pull-down impedance code NCODE<1:M> in response to the second up/down signal UP/DN2.

The pull-down impedance unit 730 is configured to pull-down drive the second node ND2 using an impedance value thereof decided by the pull-down impedance code NCODE<1:M>. In an embodiment, the pull-down impedance unit 730 may include a plurality of NMOS transistors coupled in parallel to the second node ND2 and turned on/off in response to the respective bits of the pull-down impedance code NCODE<1:M>. The operation of the pull-down impedance unit 730 can be explained in a similar manner to that of the pull-up impedance unit 530 described above. Thus, to avoid duplicate explanation, detailed descriptions to the pull-down impedance unit 730 will be omitted in this embodiment.

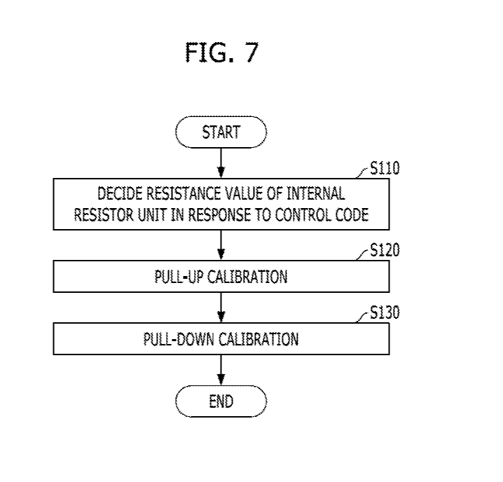

FIG. 7 is a flow chart showing an operation of the impedance control circuit illustrated in FIG. 6 according to an embodiment of the present invention.

Before the impedance control circuit operates, in a resistance measurement mode, e.g., when the test mode signal TM is at a high logic level, the storage unit 450 stores the control code RCTR<1:N> corresponding to the target resistance value of the internal resistor unit 300 by performing a resistance measuring operation. Here, the operation of the resistance measurement mode is similar to the operation of the resistance measuring circuit described with reference to FIGS. 4 and 5. First, the operation of the resistance measurement mode will be described with reference to FIGS. 5 and 6. In the resistance measurement mode, the test mode signal TM is inputted at a high logic level. At step S10, in response to the high-level test mode signal TM, the control code select unit 460 selects the control code TRCTR<1:N> inputted from outside as a control code RCTR<1:N> and transmits the control code RCTR<1:N> to the internal resistor unit 300. At step S15, the resistance value of the internal resistor unit 300 is decided in response to the control code RCTR<1:N> inputted to the internal resistor unit 300. Then, the path control signal PATH_CTR is activated at step S20, and the resistance value of the first path PATH1 is measured by the resistance measuring unit (not illustrated in FIG. 6) connected to the calibration pad ZQ PAD at step 30. At step S40, the path control signal PATH_CTR is deactivated, and the resistance value of the second path PATH2 is measured by the resistance measuring unit at step S50. Then, at step S60, the resistance value of the internal resistor unit 300 is calculated by subtracting the resistance value of the second path PATH2 from the measured resistance value of the first path PATH1. When the calculated resistance value of the internal resistor unit 300 is not equal to the target resistance value, another control code TRCTR<1:N> is inputted from outside at step S80, and the steps S15 to S70 are repeated. In an embodiment, the step S50 may be performed only once since the resistance value of the second path PATH2, i.e., R_MSR+R_PAD+R_PATH, is substantially constant. When the calculated resistance value of the internal resistor unit 300 reaches the target resistance value, the control code RCTR<1:N> at that time is stored in the storage unit 450 as the control code FRCTR<1:N> at step S85. When the storage unit 450 includes a fuse circuit, the control code RCTR<1:N> corresponding to the target resistance value is programmed into the fuse circuit at step S85.

Next, the operation of the impedance control circuit will be described with reference to FIGS. 6 and 7. In a normal mode in which the operation of the impedance control circuit starts, the test mode signal TM is inputted at a low logic level. The control code select unit 460 selects the control code FRCTR<1:N> stored in the storage unit 450 as the control code RCTR<1:N> and transmits the selected control code RCTR<1:N> to the internal resistor unit 300. The resistance value of the internal resistance unit 300 is decided in response to the transmitted control code RCTR<1:N> at step S110.

Meanwhile, when the test mode signal TM is at a low logic level in the normal mode, the path control signal PATH_CTR is inputted at a low logic level. As a result, the path control unit 200 couples the calibration pad ZQ PAD to the ground node, instead of the internal resistor unit 300. That is, during an operation period of the impedance control circuit, the calibration pad ZQ PAD and the internal resistor unit 300 are not coupled to each other. On the other hand, the first node switch S_ND1 is turned on in response to the inverted path control signal /PATH_CTR that is at a high logic level so that the internal resistor unit 300 and the first node ND1 are coupled to each other.

The first comparison section 510 compares the voltage of the first node ND1 to the reference voltage VREF and generates the first up/down signal UP/DN1. The voltage of the first node ND1 is generated by voltage division between the internal resistor unit 300 and the pull-up impedance unit 530. The first counter section 520 increases or decreases the value of the pull-up impedance code PCODE<1:M> in response to the first up/down signal UP/DN1. The pull-up impedance code PCODE<1:M> selectively turns on/off the PMOS transistors of the pull-up impedance unit 530 to control the impedance value of the pull-up impedance unit 530. The controlled impedance value of the pull-up impedance unit 530 changes the voltage of the first node ND1, and the above-described operation is repeated until the impedance value of the pull-up impedance unit 530 becomes equal to the impedance value of the internal resistor unit 300, at step S120. As a result, the pull-up calibration operation is completed.

The pull-up impedance code PCODE<1:M> determined by the pull-up calibration operation is applied to the dummy impedance unit 600 to decide the impedance value of the dummy impedance unit 600.

Then, the pull-down calibration operation starts at step S130. The pull-down calibration operation is performed in a similar manner to the pull-up calibration operation. The second comparison section 710 and the second counter section 720 are used to perform the pull-down calibration until the voltage of the second node ND2 is equal to the reference voltage VREF. As a result, the impedance value of the pull-down impedance unit 730 becomes equal to the impedance value of the dummy impedance unit 600, so that the pull-down calibration operation is completed.

According to the embodiment of the present invention, the impedance codes PCODE<1:M> and NCODE<1:M> may be generated using internal resistors, instead of external resistors. More specifically, the impedance control circuit according to the embodiment of the present invention may generate the impedance codes PCODE<1:M> and NCODE<1:M> for controlling a termination impedance value, using the internal resistance unit 300 which includes the internal resistors.

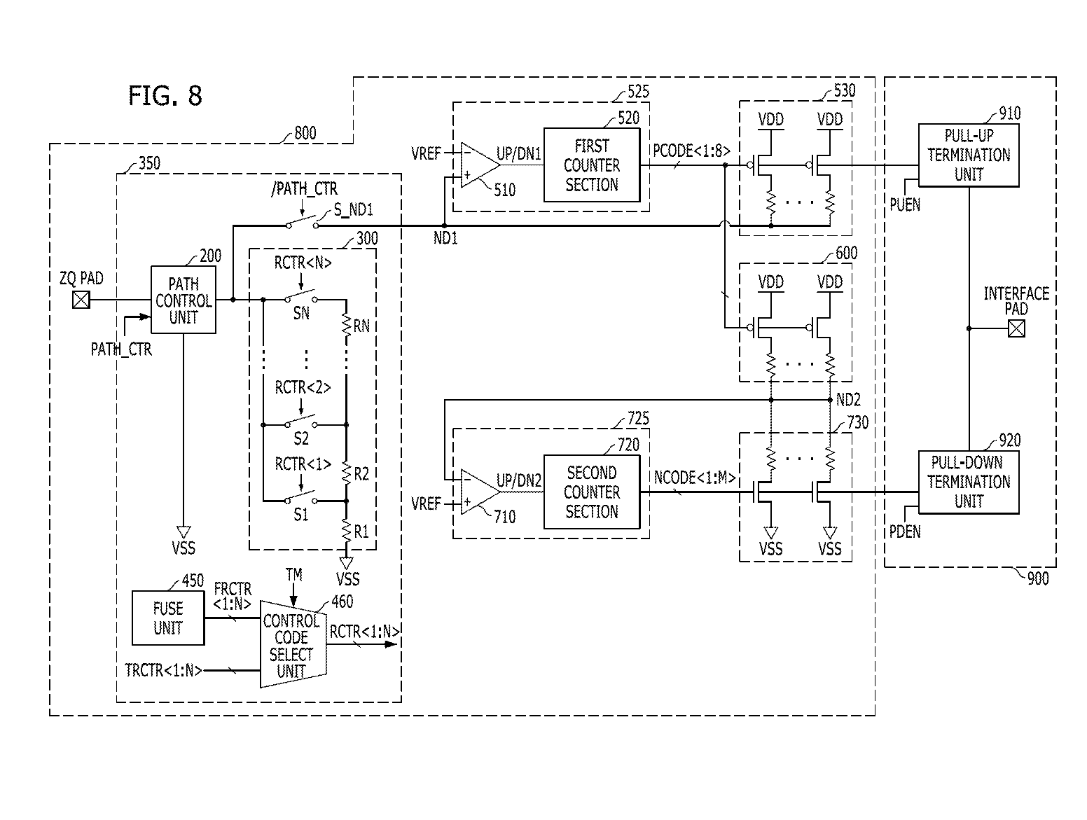

FIG. 8 is a diagram illustrating a semiconductor device according to an embodiment of the present invention.

Referring to FIG. 8, the semiconductor device includes an impedance control circuit 800 and a termination circuit 900.

The impedance control circuit 800 is configured to generate a pull-up impedance code PCODE<1:M> and a pull-down impedance code NCODE<1:M> for controlling a termination impedance value, and to output the generated impedance codes PCODE<1:M> and NCODE<1:M> to the termination circuit 900. The impedance control circuit 800 may be designed to have the impedance control circuit illustrated in FIG. 6.

The termination circuit 900 is configured to receive the impedance codes PCODE<1:M> and NCODE<1:M> and terminate an interface pad INTERFACE PAD. In an embodiment, the termination circuit 900 may include a pull-up termination unit 910 and a pull-down termination unit 920.

The pull-up termination unit 910 may be configured in a similar manner to the pull-up impedance unit 530 to receive the same pull-up impedance code PCODE<1:M>. Therefore, the pull-up termination unit 910 has the same impedance value as that of the pull-up impedance unit 530. In an embodiment, the pull-up termination unit 910 may have the impedance value of 240Ω that is the same as that of the pull-up impedance unit 530. In another embodiment, the impedance value of the pull-up termination unit 910 may be controlled to have 120Ω or 60Ω that is different from the impedance value of the pull-up impedance unit 530.

A pull-up termination enable signal PUEN is a signal for controlling the activation of the pull-up termination unit 910. That is, the pull-up termination unit 910 is activated in response to the pull-up termination enable signal PUEN, and thus the impedance value of the pull-up termination unit 910 is decided by the pull-up impedance code PCODE<1:M>.

The pull-down termination unit 920 is designed in a similar manner to the pull-down impedance unit 730 to receive the same pull-down impedance code NCODE<1:M>. Therefore, the pull-down termination unit 920 has the same impedance value as that of the pull-down impedance unit 730. In an embodiment, the pull-down termination unit 920 may have the same impedance value of 240Ω as the pull-down impedance unit 730. In another embodiment, the impedance value of the pull-down termination unit 920 may be controlled to have 120Ω or 60Ω that is different from the impedance value of the pull-down impedance unit 730.

A pull-down termination enable signal PDEN is a signal for controlling the activation of the pull-down termination unit 920. That is, the pull-down termination unit 920 is activated in response to the pull-down termination enable signal PDEN, and thus the impedance value of the pull-down termination unit 920 is decided by the pull-down impedance code NCODE<1:M>.

In an embodiment, the termination circuit 900 may include an output driver (not shown) to output data in a semiconductor device or the like. When the pull-up termination enable signal PUEN is activated for the pull-up termination unit 910 to pull-up terminate the interface pad INTERFACE PAD (e.g., DQ pad), high-level data may be outputted through the interface pad INTERFACE PAD, and when the pull-down termination enable signal PDEN is activated for the pull-down termination unit 920 to pull-down terminate the interface pad INTERFACE PAD, low-level data may be outputted through the interface pad INTERFACE PAD.

According to the embodiments of the present invention, a resistance value of a resistor embedded in an integrated circuit chip may be precisely measured to improve the stability and reliability of the integrated circuit chip.

In addition, since an impedance code for controlling an impedance value is generated using internal resistors instead of external resistors used in a conventional calibration circuit, it is possible to reduce the system cost.

While the present invention has been described with respect to the specific embodiments, it will be apparent to those skilled in the art that various changes and modifications may be made without departing from the spirit and scope of the invention as defined in the following claims.

What is claimed is:

1. A resistance measuring method comprising:
receiving a control code;
measuring a resistance value of a first path which is formed from an interface pad through a resistor unit to a ground node, wherein the resistor unit is included in an integrated circuit chip and a resistance value of the resistor unit is determined in response to the control code;
measuring a resistance value of a second path which is formed from the interface pad to the ground node without passing through the resistor unit; and
calculating the resistance value of the resistor unit by subtracting the resistance value of the second path from the resistance value of the first path.

2. The resistance measuring method of claim 1, further comprising, storing the control node when the calculated resistance value of the resistor unit is substantially the same as a target resistance value.

3. The resistance measuring method of claim 1, further comprising:
determining whether the calculated resistance value of the resistor unit is substantially the same as a target resistance value;
receiving a new control code if it is determined that the calculated resistance value of the resistor unit is not substantially the same as the target resistance value;
measuring the resistance value of the first path corresponding to the new control code; and
calculating the resistance value of the resistor unit by subtracting the resistance value of the second path from the resistance value of the first path,
wherein the above steps are repeatedly performed until the calculated resistance value of the resistor unit is substantially the same as the target resistance value.

4. The resistance measuring method of claim 3, further comprising, storing the new control code when the calculated resistance value of the resistor unit is substantially the same as the target resistance value.

5. A resistance measuring circuit comprising:
an interface pad;
a resistor unit;
a path control unit configured to form a first path from the interface pad through the resistor unit to a ground node or a second path from the interface pad to the ground node in response to a path control signal; and
a resistance measuring unit coupled to the interface pad and configured to measure a resistance value of the first path and a resistance value of the second path,
wherein the interface pad, the resistor unit, and the path control unit are included in an integrated circuit chip.

6. The resistance measuring circuit of claim 5, further comprising a calculation unit configured to calculate a resistance value of the resistor unit by subtracting the resistance value of the second path from the resistance value of the first path.

7. The resistance measuring circuit of claim 6, further comprising a storage unit configured to store a target control code for controlling the internal resistor unit to have a target resistance value.

8. The resistance measuring circuit of claim 7, wherein the storage unit comprises a fuse circuit in which the target control code is programmed.

9. The resistance measuring circuit of claim 7, wherein the target control code is determined by:
receiving a first control code;
measuring a resistance value of the first path corresponding to the first control code and the resistance value of the second path through the use of the resistance measuring unit;
calculating the resistance value of the internal resistor unit by subtracting the resistance value of the second path from the resistance value of the first path through the use of the calculation unit;
determining whether the calculated resistance value of the resistor unit is substantially the same as the target resistance value through the use of the calculation unit;
receiving a second control code if it is determined that the calculated resistance value of the resistor unit is not substantially the same as the target resistance value;
repeating the above steps until the calculated resistance value of the internal resistor unit is substantially the same as the target resistance value; and
determining as the target control code the first or second control code when the calculated resistance value of the internal resistor unit is substantially the same as the target resistance value.

10. The resistance measuring circuit of claim 9, wherein the target control code is determined in a test mode.

11. An impedance control circuit of an integrated circuit chip, the circuit comprising:
an internal resistor unit;
a first code generation unit configured to generate a first impedance code for controlling a first impedance value using a voltage of a first impedance node coupled to the internal resistor unit; and
a first impedance unit configured to have the first impedance value decided by the first impedance code and coupled to the first impedance node.

12. The impedance control circuit of claim 11, further comprising:
a second impedance unit configured to have the first impedance value decided by the first impedance code and coupled to a second impedance node;
a second code generation unit configured to generate a second impedance code for controlling a second impedance value using a voltage of the second impedance node; and
a third impedance unit configured to have the second impedance value decided by the second impedance code and coupled to the second impedance node.

13. The impedance control circuit of claim 11, further comprising a storage unit configured to store a target control code for controlling the internal resistor unit to have a target resistance value.

14. The impedance control circuit of claim 11, wherein the storage unit comprises a fuse circuit in which the target control code is programmed.

15. The impedance control circuit of claim 11, wherein the target control code is determined by:
receiving a first control code;
measuring a resistance value of a first path which is formed from an interface pad through the internal resistor unit to a ground node;
measuring a resistance value of a second path which is formed from the interface pad to the ground node without passing through the internal resistor unit;
calculating the resistance value of the internal resistor unit by subtracting the resistance value of the second path from the resistance value of the first path;
determining whether the calculated resistance value of the resistor unit is substantially the same as the target resistance value;
receiving a second control code if it is determined that the calculated resistance value of the resistor unit is not substantially the same as the target resistance value;
repeating the above steps until the calculated resistance value of the internal resistor unit is substantially the same as the target resistance value; and
determining as the target control code the first or second control code when the calculated resistance value of the internal resistor unit is substantially the same as the target resistance value.

16. The impedance control circuit of claim 11, wherein the target control code is determined in a test mode.

17. The impedance control circuit of claim 11, further comprising a control code select unit configured to select either a control code provided from an external node outside the integrated circuit chip or the target control code stored in the storage unit as a control signal for determining a resistance value of the internal resistor unit in response to a test mode signal and to transmit the selected control code to the internal resistor unit.
